(19) United States
(12) Patent Application Publication
(10) Pub. No.: US 2020/0365612 A1
(43) Pub. Date: Nov. 19, 2020

(54) THREE DIMENSIONAL MEMORY DEVICE AND METHOD FOR FABRICATING THE SAME

(71) Applicant: MACRONIX INTERNATIONAL CO., LTD., Hsinchu (TW)

(72) Inventors: Chih-Wei HU, Miaoli County (TW); Teng-Hao YEH, Hsinchu City (TW); Yu-Wei JIANG, Hsinchu City (TW)

(21) Appl. No.: 16/413,706

(22) Filed: May 16, 2019

(51) Int. Cl. H01L 27/11582; H01L 23/528; H01L 23/522; H01L 29/417; H01L 21/28; H01L 27/1157; H01L 21/768; H01L 21/311; H01L 21/02

(52) U.S. Cl. CPC H01L 27/11582; H01L 21/02595; H01L 23/5226; H01L 29/41741; H01L 21/28282; H01L 27/1157; H01L 21/76897; H01L 21/31116; H01L 21/31144; H01L 21/02271; H01L 21/0262; H01L 21/02164; H01L 21/0217; H01L 21/02532; H01L 23/528

(57) ABSTRACT

A 3D memory device includes a multi-layers stacking structure, a memory layer, a channel layer, and a switching element. The multi-layers stacking structure includes a plurality of conductive layers, a plurality of insulating layers, and an opening. The insulating layer and the conductive layer are stacked along a stacking direction in a staggered manner, and the opening passes through the conductive layer. The memory layer is disposed in the opening and at least partially overlaps the conductive layers. The channel layer is disposed in the opening and overlaps the memory layer. The switching element includes a channel plug disposed over the multi-layers stacking structure and electrically connecting to the channel layer, a first gate dielectric layer surrounding the channel plug, and at gate surrounding the gate dielectric layer.

### BACKGROUND

### Technical Field

The disclosure in generally relates to a memory device and method for fabricating the same, and more particularly to a high-density three dimensional (3D) memory device and method for fabricating the same.

### Description of the Related Art

Memory devices are important device to a portable electric apparatus, such as a MP3 displayer, a digital camera, a notebook, a cell phone . . . and so on, for data storage. As the increasement of applications and functions required by the users, the trend for the memory devices pursues higher storage density and smaller cell size. To satisfy this requirement, designers have been looking for techniques to provide a 3D memory device with stacked multiple planes of memory cells, such as a vertical-channel (VC) NAND flash memory device.

A typical NAND flash memory device uses a thin film transistor having a multi-layers dielectric charge trapping structure as a memory cell and a string/ground selection switch for a memory cell string, and adopts a higher drain or source voltage and a lower (or floating) gate voltage to induce a band-to-band tunneling (BBT) and causing a gate induced drain leakage (GIDL) current to erase the memory cell string. However, the holes generated by BBT and accelerated by the transverse electric field may be injected into the gate oxide layer of the thin film transistor, which often causes charge accumulation; and the string/ground selection switch using the charge trapping thin film transistor may not be turn on again during the subsequent programing operation due to the charge accumulation, then resulting the memory cell string invalid.

Therefore, there is a need of providing an improved 3D memory device and the method for fabricating the same to obviate the drawbacks encountered from the prior art.

### SUMMARY

One aspect of the present disclosure is to provide a 3D memory device, wherein the 3D memory device includes a multi-layers stacking structure, a memory layer, a channel layer, and a switching element. The multi-layers stacking structure includes a plurality of conductive layers, a plurality of insulating layers, and at least one opening. The insulating layer and the conductive layer are stacked along a stacking direction in a staggered manner, and the opening passes through the conductive layer. The memory layer has an oxide-nitride-oxide (ONO) structure disposed in the opening and at least partially overlapping the conductive layers. The channel layer is disposed in the opening and at least partially overlaps the memory layer. The switching element includes a channel plug disposed over the multi-layers stacking structure and electrically connecting to the channel layer, a gate dielectric layer surrounding the channel plug, and a gate surrounding the gate dielectric layer.

Another aspect of the present disclosure is to provide a method for fabricating a 3D memory device, wherein the method includes steps as follows: A multi-layers stacking structure including a plurality of conductive layers, a plurality of insulating layers, and at least one opening is provided, wherein the insulating layer and the conductive layer are stacked along a stacking direction in a staggered manner, and the opening passes through the conductive layer. A memory layer is formed in the opening and at least partially overlapping the conductive layer. A channel layer is formed in the opening and at least partially overlapping the memory layer. A switching element is formed over the multi-layers stacking structure, wherein the switching element includes a channel plug electrically connecting to the channel layer, a gate dielectric layer without possessing a dielectric charge trapping structure and surrounding the channel plug, and a gate surrounding the gate dielectric layer.

In accordance with the aforementioned embodiments of the present disclosure, a 3 D memory device and the method for fabricating the same are provided. By using a switching element that does not have a gate dielectric layer including a multi-layers dielectric charge trapping structure to serve as a string selection switch/ground selection switch for a memory cell string in a 3D memory device, it is possible to avoid the use of GIDL triggered by BBT to erase the memory cell string. Therefore, the problems of failing turn on the string/ground selection switches during a subsequent programing operation due to charge accumulation can be solved.

In some embodiments of the present disclosure, the structure and method can be applied to a 3D memory device having GAA structure, a 3D memory device with a single-gate vertical channel (SGVC) structure, a 3D memory device with a cylindrical channel structure, a 3D memory device with an U-shaped vertical channel structure or a 3D memory device with a hemi-cylindrical channel structure.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A is a prospective view illustrating a multi-layers stacking structure in accordance with one embodiment of the present disclosure;

FIG. 1B is a cross-sectional view taken along the cutting line S1 as shown in FIG. 1A;

FIG. 2A is a top view illustrating the results after the multi-layers stacking structure is subjected to a patterning process to form a plurality of O-shaped openings;

FIG. 2B is a cross-sectional view taken along the cutting line S2 as shown in FIG. 2A;

FIG. 3A is a top view illustrating the results after a memory layer, a channel layer and a plurality of dielectric pillars are formed on the structure as depicted in FIG. 2A;

FIG. 3B is a cross-sectional view taken along the cutting line S3 as shown in FIG. 3A;

FIG. 4A is a top view illustrating the results after an etching back process formed in the structure as depicted in FIG. 3A;

FIG. 4B is a cross-sectional view taken along the cutting line S4 as shown in FIG. 4A:

FIG. 5A is a top view illustrating the results after a plurality of landing contact pads are formed in the structure as depicted in FIG. 4A;

FIG. 5B is a cross-sectional view taken along the cutting line S5 as shown in FIG. 5A;

FIG. 6A is a top view illustrating the results after a dielectric protection layer, a gate material layer and a dielectric capping layer are formed in the structure as depicted in FIG. 5A;

FIG. 6B is a cross-sectional view taken along the cutting line S6 as shown in FIG. 6A;

FIG. 7A is a top view illustrating the results after a plurality of through holes are formed in the structure as depicted in FIG. 6A;

FIG. 7B is a cross-sectional view taken along the cutting line S7 as shown in FIG. 7A;

FIG. 8A is a top view illustrating results after a gate dielectric layer is formed in the structure as depicted in FIG. 7A;

FIG. 8B is a cross-sectional view taken along the cutting line S8 as shown in FIG. 8A;

FIG. 9A is a top view illustrating results after a portion of the dielectric protection layer is removed from the structure as depicted in FIG. 8A;

FIG. 9B is a cross-sectional view taken along the cutting line S9 as shown in FIG. 9A;

FIG. 10A is a top view illustrating results after a plurality of channel plugs are formed in the structure as depicted in FIG. 9A;

FIG. 10B is a cross-sectional view taken along the cutting line S10 as shown in FIG. 10A;

FIG. 11A is a prospective view illustrating results after a plurality of grooves are formed in the structure as depicted in FIG. 10A;

FIG. 11B is a cross-sectional view taken along the cutting line S11 as shown in FIG. 11A;

FIGS. 12A and 12B are a prospective view and a cross-sectional view respectively illustrating a 3D memory device in accordance with one embodiment of the present embodiment;

FIG. 13 is a cross-sectional view illustrating a 3D memory device in accordance with another embodiment of the present embodiment; and

FIG. 14 is a cross-sectional view illustrating a 3D memory device in accordance with yet another embodiment of the present embodiment.

### DETAILED DESCRIPTION

The embodiments as illustrated below provide a 3D memory device and the method for fabricating the same to solve the problems of the string/ground selection switch using a charge trapping thin film transistor cannot be turn on due to an undesired GIDL current. The present disclosure will now be described more specifically with reference to the following embodiments illustrating the structure and arrangements thereof.

It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present disclosure. In addition, the illustrations may not be necessarily be drawn to scale, and the identical elements of the embodiments are designated with the same reference numerals.

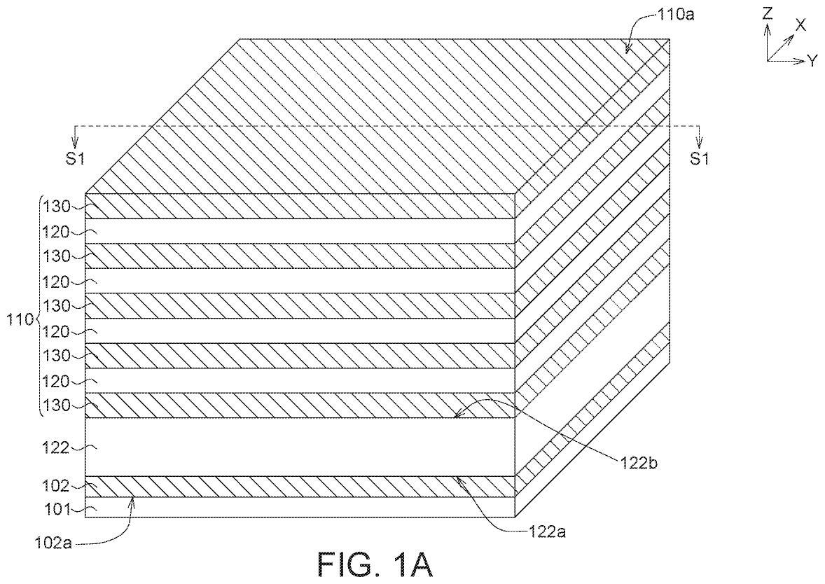

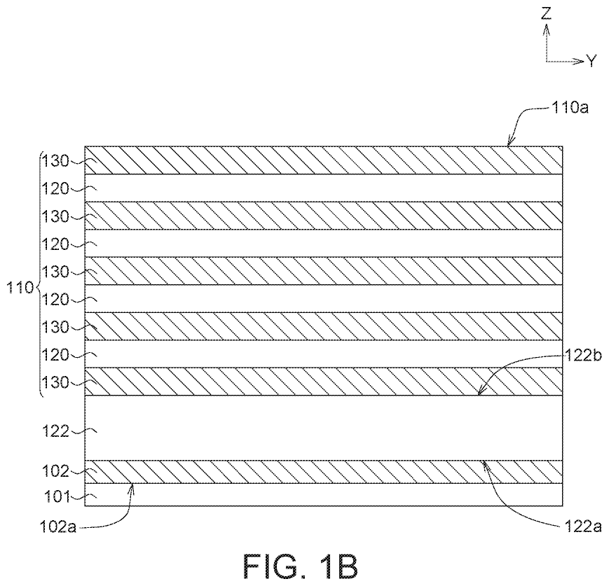

The method for fabricating the 3D memory device 100 includes steps as follows: Firstly, a multi-layers stacking structure 110 including a plurality of conductive layers 120 and a plurality of insulating layers 130 stacked in a staggered manner on a substrate 101 is firstly provided. FIG. 1A is a prospective view illustrating a multi-layers stacking structure 110 in accordance with one embodiment of the present disclosure; and FIG. 1B is a cross-sectional view taken along the cutting line S1 as shown in FIG. 1A.

In some embodiments of the present disclosure, the 3D memory device 100 may further include a bottom gate layer 122 and a buried oxide layer 102 disposed between the substrate 101 and the multi-layers stacking structure 110. In the present embodiment, the buried oxide layer 102 is formed by a thermal oxidation process directly performed on a surface of the substrate 101; the bottom gate layer 122 is formed by a process of depositing a conductive material on the buried oxide layer 102; and the conductive layers 120 and the plurality of insulating layers 130 are stacked in a staggered manner, on the bottom gate layer 122, along a stacking direction parallel to the Z-axis to form the multi-layers stacking structure 110. However, in some embodiments of the present disclosure, the buried oxide layer 102 can be also formed by a deposition process performed on the surface of the substrate 101.

The conductive layers 120 can be formed of metal (such as copper (Cu), aluminum (Al), tungsten (W) or the metal ally thereof), doped or undoped semiconductor material (such as epitaxial single crystal silicon or poly-silicon (Si)/germanium (Ge) or other suitable material. The insulating layers 130 can be formed of a dielectric material such as silicon oxide, silicon nitride, silicon oxynitride, silicate, or others. The buried oxide layer 102 can be formed of silicon oxide. The material made of the conductive layers 120 may be identical to or different from that made of the bottom gate layer 122; and the material made of the insulating layers 130 may be identical to or different from that made of the buried oxide layer 102.

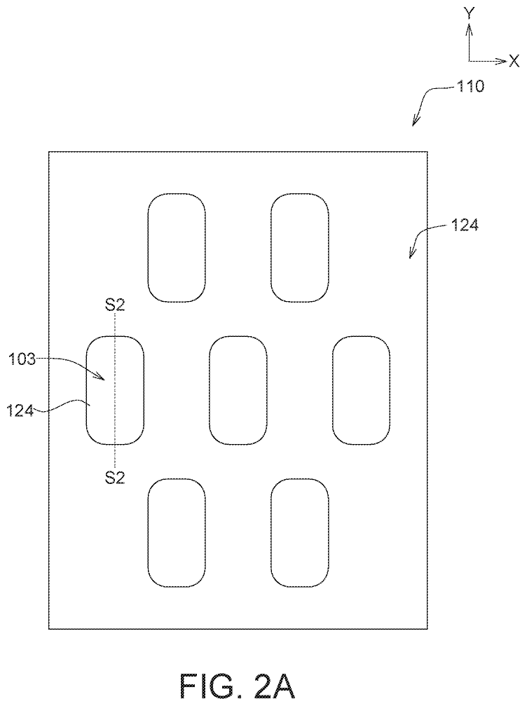

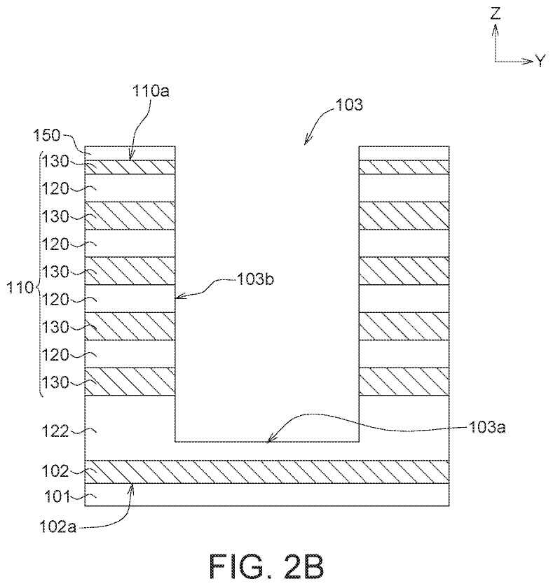

Next, the multi-layer stack 110 is patterned to form a plurality of O-shaped openings 103 penetrating through the conductive layer 120. FIG. 2A is a top view illustrating the results after the multi-layers stacking structure 110 is subjected to a patterning process to form a plurality of O-shaped openings 103; and FIG. 2B is a cross-sectional view taken along the cutting line S2 as shown in FIG. 2A.

In some embodiments of the present disclosure, the process for patterning the multi-layers stacking structure 110 comprises steps as follows: A patterned hard mask layer 150 is firstly provided on a top surface of the multi-layers stacking structure 110, and an anisotropic etching process, such as reactive ion etching (RIE) process is performed using the patterned hard mask 150 as an etching mask to remove a portion of the multi-layers stacking structure 110, so as to form a plurality of the O-shaped openings 103 extending along the Z-axis.

In the present embodiment, the patterning process may be stopped in the buried oxide layer 102 to make portions of the conductive layers 120, the insulating layers 130, the bottom gate layer 122 and the buried oxide layer 102 exposed from the O-shaped openings 103. In other words, these 0-shaped openings 103 may not penetrate through the bottom surface 102a of the buried oxide layer 102 to expose the semiconductor material of the substrate 101. The bottom 103a of the O-shaped openings 103 respectively have a height measured from the substrate 101 substantially higher than that of the bottom surface 102a of the buried oxide layer 102. However, the depths of the O-shaped openings 103 are not limited to these regards. For example, in some embodiments of the present disclosure, the patterning process for forming the O-shaped openings 103 may be stopped in the bottom gate layer 122. In other words, the O-shaped openings 103 may not penetrate through the bottom gate layer 122 to expose the buried oxide layer 102. The O-shaped openings 103 may have a bottom 103a disposed on a location separated upwards from the bottom surface 122a of the bottom gate layer 122 for a distance, wherein the distance is about (but not limited to) ⅓ thickness of the bottom gate layer 122.

The “O-shaped opening 103” as described here can be any recess structure extending into the multi-layers stacking structure 110 from the top surface 110a of the multi-layers stacking structure 110 along the Z-axis and having an O-shaped cross-sectional profile substantially parallel to the top surface 110a. In some embodiments of the present disclosure, the O-shaped cross-sectional profile can be a circle, an oval, and egg shape or a rounded rectangle. For example, in one embodiment, the “O-shaped opening” as described here can be a wedge-shaped opening flaring from the bottom to the top surface 110a of the multi-layers stacking structure 110 and having a plurality of rounded rectangular cross-sectional profiles parallel to the top surface 110a. In some embodiments of the present embodiments, the O-shaped cross-sectional profile can be an oval. According to the natures of the etching process for forming the O-shaped openings 103, the oval cross-sectional profile of the portion of the O-shaped openings 103 adjacent to the top surface 110a of the multi-layers stacking structure 110 has a size greater than the size of the oval cross-sectional profile of the portion of the O-shaped opening 103 adjacent to the bottom surface 122a of the bottom gate layer 122. This design can balance the control ability on the top and bottom of the multi-layers stacking structure 110, and the processes subsequently performed thereon may be benefit with it.

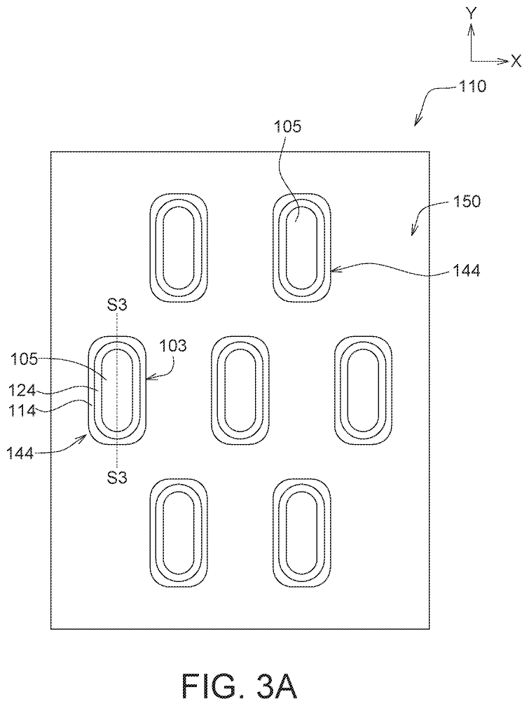

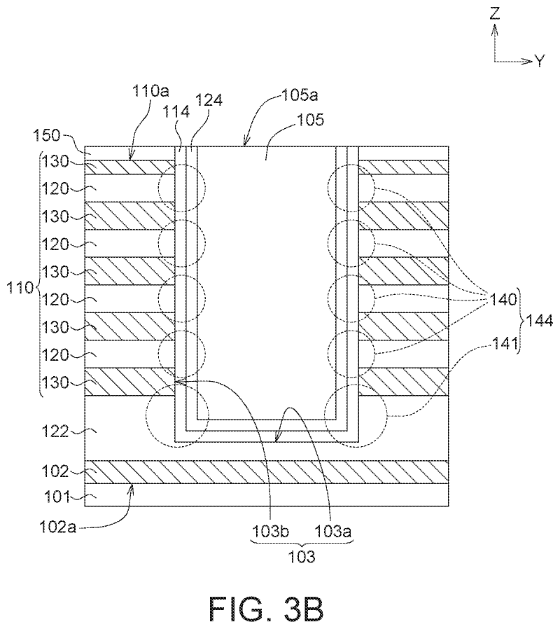

Thereinafter, a memory layer 114, a channel layer 124 and a plurality dielectric pillar 105 are sequentially formed in the O-shaped openings 103 to cover the sidewall 103b and the bottom 103a thereof. FIG. 3A is a top view illustrating the results after the memory layer 114 and a channel layer 124 are formed on the structure as depicted in FIG. 2A; and FIG. 3B is a cross-sectional view taken along the cutting line S3 as shown in FIG. 3A. In some embodiments of the present disclosure, the memory layer 114 is firstly formed on the multi-layers stacking structure 110 by a deposition process (such as a low pressure chemical vapor deposition (LPCVD)) and blanket over the sidewall 103b and the bottom 103a of each O-shaped opening 103. The channel layer 124 is then formed to cover the memory layer 114 by another deposition process (such as a LPCVD).

In some embodiment of the present disclosure, the memory layer 114 may be formed of a composite layer including a silicon oxide layer, a silicon nitride layer, and a silicon oxide layer (i.e., an ONO structure). However, the structure of the memory layer 114 is not limited to this regard. In some other embodiments, the composite layer of the memory material layer 114 may be selected from a group consisting of an oxide-nitride-oxide-nitride-oxide (ONONO) structure, a silicon-oxide-nitride-oxide-silicon (SONOS) structure, a bandgap engineered silicon-oxide-nitride-oxide-silicon (BE-SONOS) structure, a tantalum nitride-aluminum oxide-silicon nitride-silicon oxide-silicon (TANOS) structure and a metal-high-k bandgap-engineered silicon-oxide-nitride-oxide-silicon (MA BE-SONOS) structure. In the present embodiment, the memory layer 114 include an ONO structure and the channel layer 124 is made of poly-silicon.

A planarization process (such as a chemical-mechanical polishing (CMP) process) using the patterned hard mask layer 150 disposed on top surface 110a of the multi-layers stacking structure 110 as a stop layer is performed to remove the portions of the channel layer 124 and the memory layer 114 disposed on the top surface 110a of the multi-layers stacking structure 110, wherein a plurality of memory cells 140 are formed on the intersectional points of the conductive layer 120 and the remaining channel layer 124 and the remaining memory layer 114; at least one tunnel field-effect transistor switch 141 is formed on the intersectional points of the bottom gate layer 122 and the memory structure layer 104; and the plurality of memory cells 140 and the tunnel field-effect transistor switch 141 formed in each O-shaped opening 103 can be electrically connected in series by the corresponding channel layer 124 to form a gate-all-around (GAA) memory cell string 144.

Thereafter, a dielectric pillar 105 is formed in each of the ach O-shaped openings 103. In some embodiments of the present disclosure, the forming of the dielectric pillars 105 may include steps as follows: A dielectric material is deposited on the multi-layers stacking structure 110 and full-filling each of the O-shaped openings 103. A planarization process (such as a CMP process) using the patterned hard mask layer 150 as a stop layer is performed to remove the portions of the dielectric material disposed on the top surface 110a of the multi-layers stacking structure 110, whereby a dielectric pillar 105 having an O-shaped cross-sectional profile parallel to the top surface 110a of the multi-layers stacking structure 110 can be formed in each of the O-shaped openings 103 (see FIG. 3B).

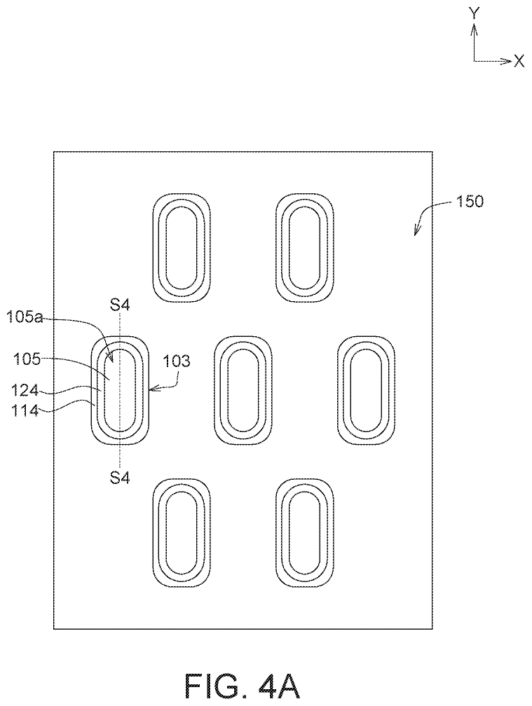

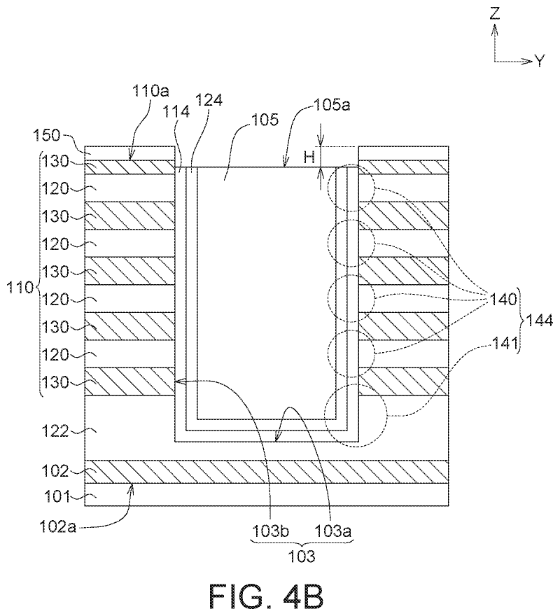

An etching back process is then performed to remove a portion of the dielectric material disposed on the top portion of the dielectric pillars 105, so as to make a top surface 105a of the dielectric pillars 105 has a step distance H1 separated from the top surface 110a of the multi-layers stacking structure 110, and to make portions of the channel layers 124 exposed from each of the O-shaped openings 103. FIG. 4A is a top view illustrating the results after the etching back process formed in the structure as depicted in FIG. 3A. FIG. 4B is a cross-sectional view taken along the cutting line S4 as shown in FIG. 4A.

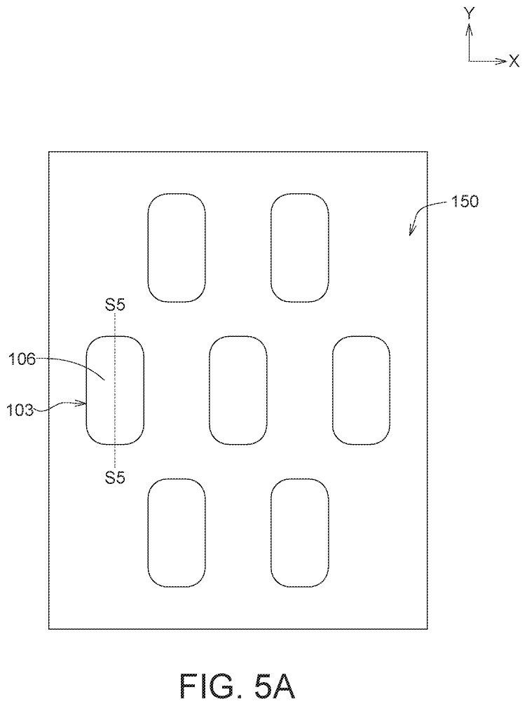

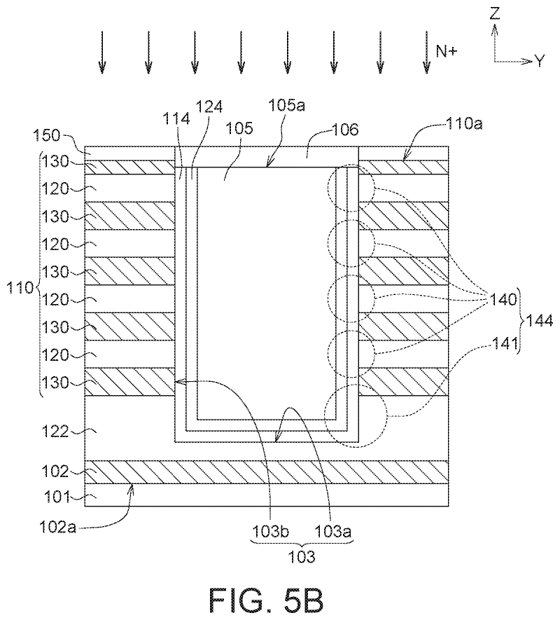

Next, a landing contact pad 106 is formed in each of the ach O-shaped openings 103. FIG. 5A is a top view illustrating the results after a plurality of landing contact pads 106 are formed in the structure as depicted in FIG. 4A; and FIG. 5B is a cross-sectional view taken along the cutting line S5 as shown in FIG. 5A. In some embodiments of the present disclosure, the forming of the landing contact pads 106 may include steps as follows: A conductive material is deposited on the multi-layers stacking structure 110 and full-filling each of the O-shaped openings 103 to form a self-align contact with the exposed portion of the corresponding channel layer 124 in each of the O-shaped openings 103. A planarization process (such as a CMP process) using the top surface 110a of the multi-layers stacking structure 110 as a stop layer is performed to remove the portions of the conductive material disposed on the top surface 110a of the multi-layers stacking structure 110. The material used to constitute the landing contact pads 106 may include metal (such as Cu, Al, W or the metal ally thereof), doped or undoped semiconductor material (such as epitaxial single crystal silicon or poly-silicon (Si)/germanium (Ge) or other suitable material. In the present embodiment, an ion implantation process can be performed on the landing contact pad 106 to drive an n-type dopant, such as phosphorus (P) or arsenic (As), (denoted as N+) is driven into the contact pad 106.

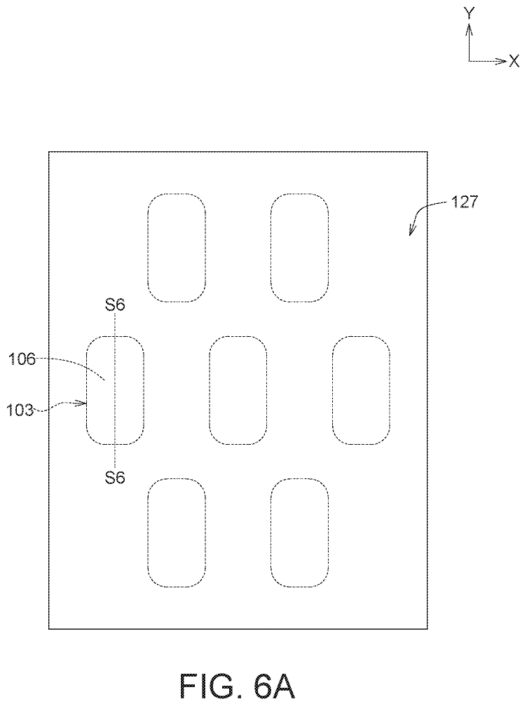

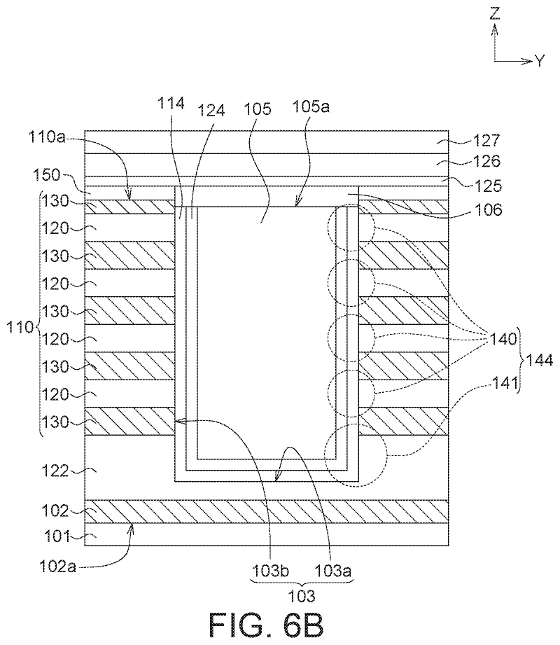

A dielectric protection layer 125, a gate material layer 126, and a dielectric capping layer 127 are sequentially formed over the multilayer stack structure 110 to cover the landing contact pads 106 and the patterned hard mask layer 150. FIG. 6A is atop view illustrating the results after the dielectric protection layer 125, the gate material layer 126 and the dielectric capping layer 127 are formed in the structure as depicted in FIG. 5A; and FIG. 6B is a cross-sectional view taken along the cutting line S6 as shown in FIG. 6A. In some embodiments of the present disclosure, the material constituting the dielectric protection layer 125 can be silicon oxide; the gate material layer 126 may include polysilicon; the material constituting the dielectric capping layer 127 may be the same as or different from the material constituting the dielectric protection layer 125.

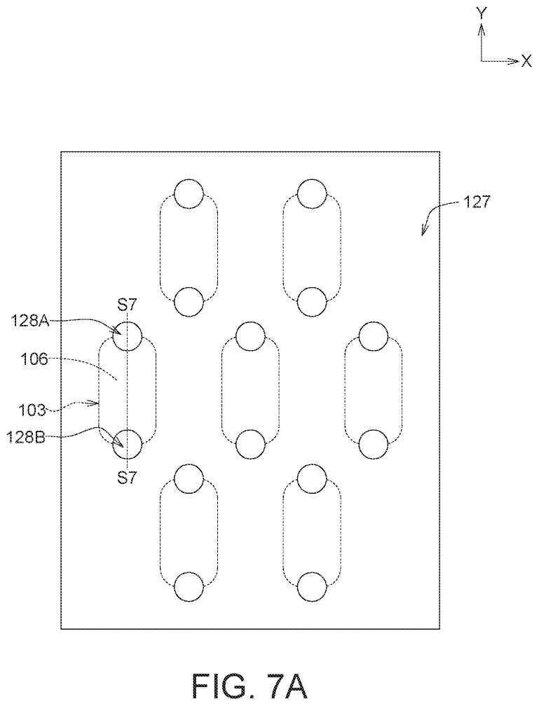

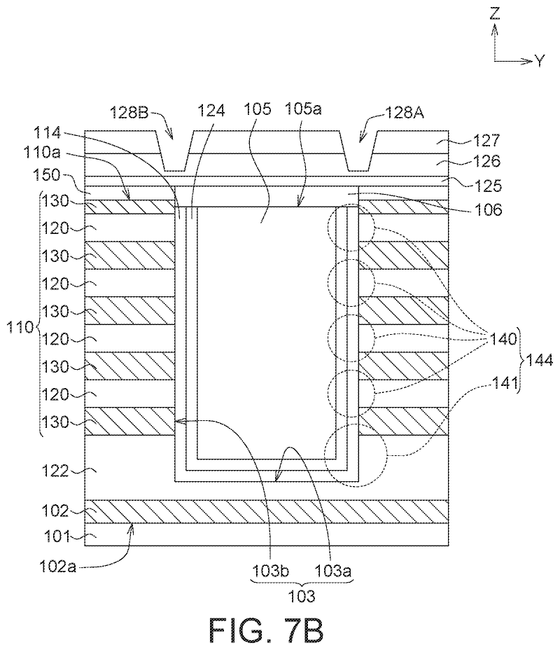

Thereafter, an etching process, using the dielectric protection layer 125 as an etch stop layer, is performed to remove a portion of the dielectric capping layer 127 and a portion of the gate material layer 126 to form a plurality of through holes, such as the through holes 128A and 128B, partially overlap the corresponding 0-shaped opening 103, respectively. FIG. 7A is a top view illustrating the results after a plurality of through holes 128A and 128B are formed in the structure as depicted in FIG. 6A; and FIG. 7B is a cross-sectional view taken along the cutting line S7 as shown in FIG. 7A. In some embodiments of the present specification, each of the O-shaped openings 103 corresponds to the two through holes 128A and 128B, respectively. For example, in the present embodiment, the through holes 128A and 128B respectively overlap the both ends of the long axis of the oval cross-sectional profile of the corresponding 0-shaped opening 103.

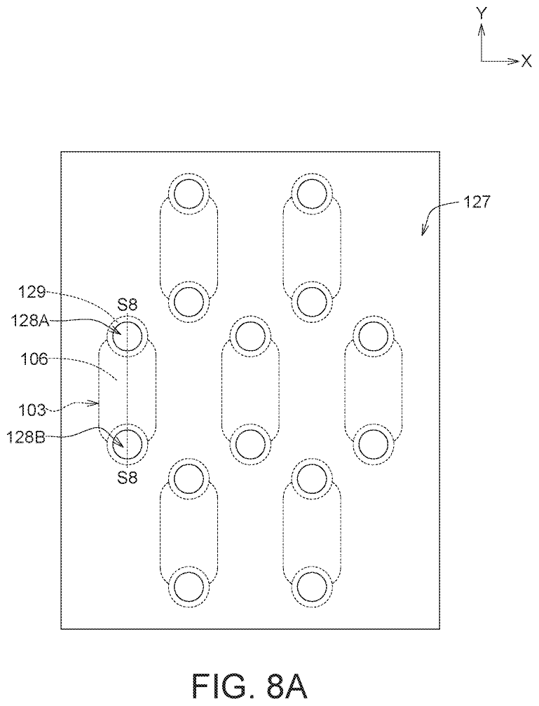

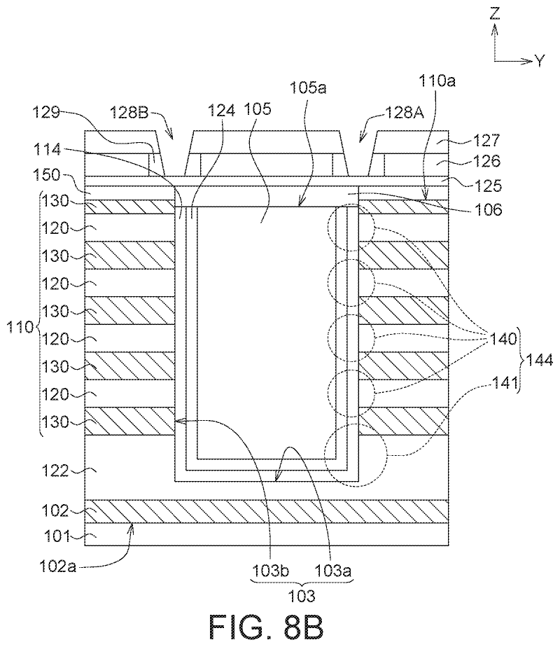

Next, a gate dielectric layer 129 is formed on the sidewalls of each of the through holes 128A and 128B. FIG. 8A is a top view illustrating results after a gate dielectric layer 129 is formed in the structure as depicted in FIG. 7A; and FIG. 8B is a cross-sectional view taken along the cutting line S8 as shown in FIG. 8A. In some embodiments of the present disclosure, the gate dielectric layer 129 is formed by a thermal oxidation process in a manner of oxidizing a portion of the gate material layer 126 exposed form each of the through holes 128A and 128B, whereby the gate dielectric layer 129 may have a ring profile.

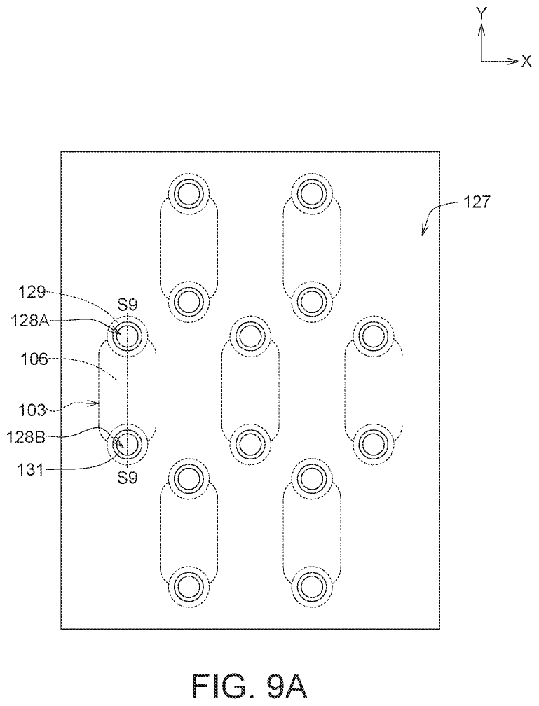

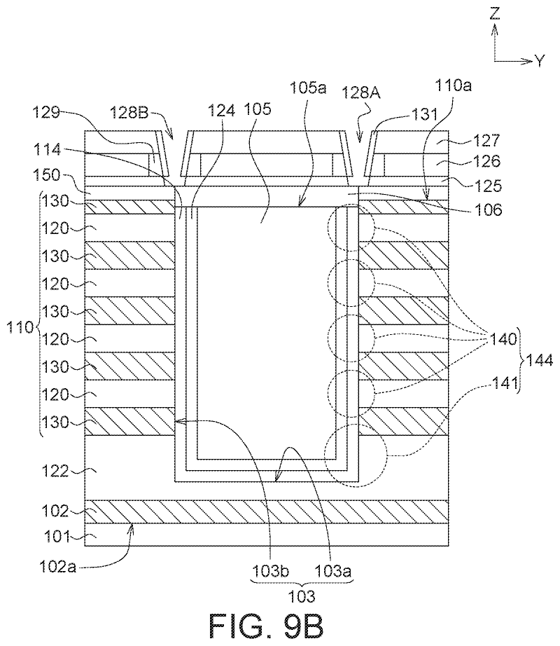

Another etch back process can be then performed to remove a portion of the dielectric protection layer 125 from the through holes 128A and 128B to expose portions of the landing contact pads 106. FIG. 9A is a top view illustrating results after a portion of the dielectric protection layer 125 is removed from the structure as depicted in FIG. 8A; and FIG. 9B is a cross-sectional view taken along the cutting line S9 as shown in FIG. 9A. In some embodiments of the present specification, in order to protect the gate dielectric layer 129, a conductive film 131, such as a polysilicon film, can be formed on the sidewalls of the through holes 128A and 128B to cover the gate dielectric layer 129 before the etch back process is performed, whereby the portion of the dielectric protection layer 125a that will be removed by the subsequent etch back process can be exposed from the through holes 128A and 128B.

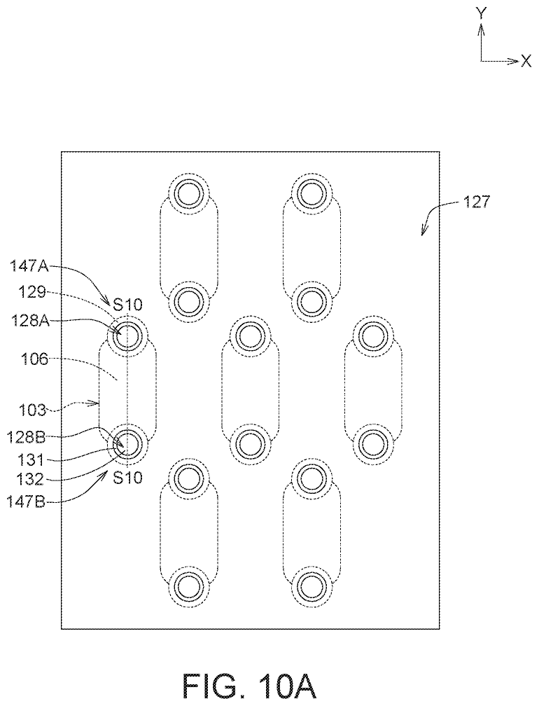

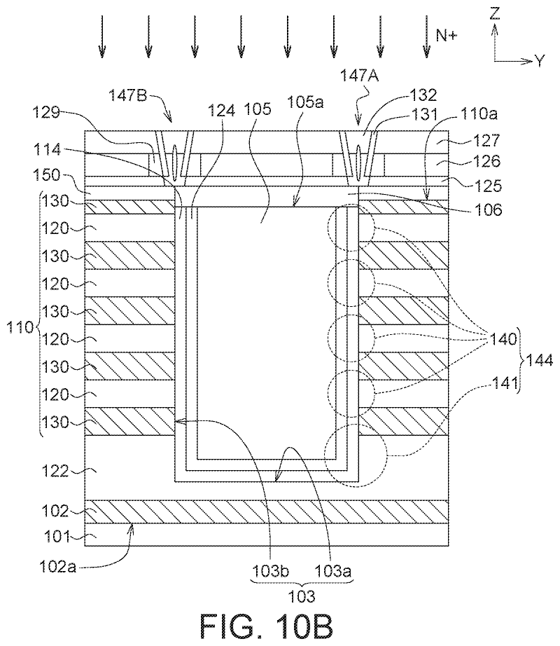

Subsequently, a channel material, such as semiconductor materials (such as polysilicon), metal silicide (such as silicon-titanium (SiTi), cobalt-silicon (CoSi) or silicon-germanium (SiGe)), oxide semiconductors (such as indium zinc oxide (ITO) or indium gallium zinc oxide (IGZO)) or combinations of two or more of the above materials are used to fill the through holes 128A and 128B to form a plurality of channel plugs 132. FIG. 10A is a top view illustrating results after a plurality of channel plugs 132 are formed in the structure as depicted in FIG. 9A; and FIG. 10B is a cross-sectional view taken along the cutting line S10 as shown in FIG. 10A. In some embodiments of the present disclosure, after forming a plurality of channel plugs 132, an n-type dopant (represented by N+), such as P or As, may be driven into the top portions of the channel plugs 132 by an ion implantation process.

Each of the channel plugs 132 disposed in the corresponding through hole 128A (or 128B) and the corresponding landing contact pad 106, the corresponding dielectric protective layer 125, the corresponding gate material layer 126, the corresponding gate dielectric layer 129, and the corresponding channel plugs 132 can form a metal-oxide-semiconductor (MOS) transistor switch, such as the MOS transistor switch 147A (or 147B) formed in the through hole 128A (or 128B), in which the portion of the channel plug 132 overlapping with the dielectric capping layer 127 and the landing contact pad 106 can serve as the source/drain of the MOS transistor switch 147A (or 147B), respectively; the portions of the channel plug 132 overlapping with the gate dielectric layer 129 and the dielectric protection layer 125 may serve as the channel region of the MOS transistor switch 147A (or 147B); the gate material layer 126 surrounding channel plug 132 may serve as the gate of the MOS transistor switch 147A (or 147B).

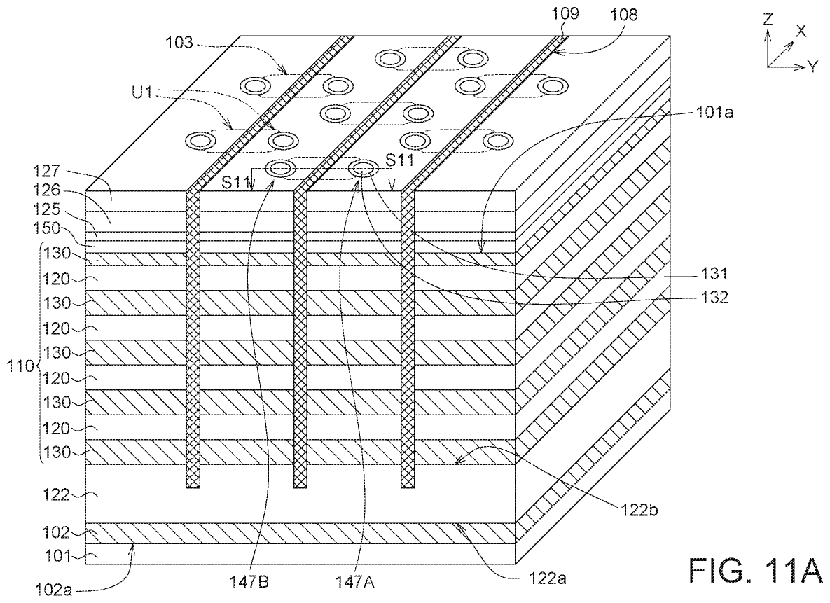

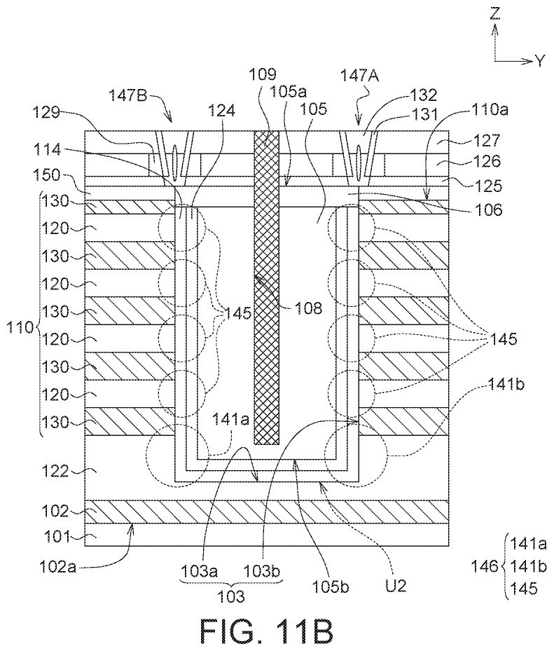

A plurality of grooves 108 are then formed in the multi-layers stacking structure 110 by an etching process, wherein each of the grooves corresponds to one of the O-shaped openings 103. FIG. 11A is a prospective view illustrating results after a plurality of grooves 108 are formed in the structure as depicted in FIG. 10A; and FIG. 11B is a cross-sectional view taken along the cutting line S11 as shown in FIG. 11A.

In some embodiments of the present disclosure, each groove 108, in one hand, extends downward from the dielectric capping layer 127 along the stacking direction parallel to the Z-axis and passes through the portions of the dielectric capping layer 127, the gate material layer 126 and the dielectric protection layer 125 overlying on the corresponding 0-shaped opening 103, as well passes through the landing contact pad 106 and the dielectric pillar 105 disposed in the corresponding 0-shaped opening 103. And in another hand, the groove 108 extends along the direction parallel to the X-axis (the direction perpendicular to the stacking direction) beyond the sidewall 103b of the corresponding O-shaped opening 103, so as to pass through the portions of the channel layer 124 and the memory layer 114 at two opposite ends of the sidewall 103b of the corresponding 0-shaped opening 103 and goes into the multi-layers stacking structure 110 and portions of the dielectric capping layer 127, the gate material layer 126 and the dielectric protection layer 125 not overlying on the corresponding 0-shaped opening 103.

In the present embodiment, the grooves 108 may not extend downwards beyond the bottom surface 105b of the dielectric pillar 105 along the direction parallel to the Z-axis. Such that each of the grooves 108 does not cut through the portion of the channel layer 124 disposed on the bottom 103a of the corresponding 0-shaped opening 103. Besides, the groove 108 may extend along the direction parallel to the X-axis (the direction perpendicular to the stacking direction) beyond the sidewall 103b of the corresponding 0-shaped opening 103, so as to laterally cut off the portions of the channel layer 124 and the memory layer 104 disposed on the sidewalls 103b of the corresponding 0-shaped opening 103, the gate material layer 126 overlying on the corresponding 0-shaped opening 103 and the landing contact pad 106 disposed in the corresponding 0-shaped opening 103, and to divide them into two parts. As a result, the MOS transistor switches 147A and 147B originally connected to each other are then insulated from each other by the corresponding groove 108.

Since the portion of the channel layer 124 and the memory layer 104 that are blanket over the sidewall 103b of each 0-shaped opening 103 has an O-shaped cross-sectional profile parallel to the top surface 110a of the multi-layers stacking structure 110, thus when the corresponding groove 108 penetrate through the portions of the memory layer 114 and the channel layer 124 disposed on the sidewall 103b of the O-shaped opening 103, each of the portions of the memory layer 114 and the channel layer 124 can be divided into two parts respectively have a U-shaped (e.g. a half of the cutting O-shape) cross-sectional profile parallel to the top surface 110a of the multi-layers stacking structure 110 (see FIG. 11A). Furthermore, hence the portion of the channel layer 124 disposed on the bottom 103a of the O-shaped opening 103 is not cut off by the groove 108, thus the channel layer 124 has another U-shaped cross-sectional profile perpendicular to the direction parallel to the X-axis (the direction perpendicular to the stacking direction) (see FIG. 11B).

In some embodiments of the present disclosure, each of the grooves 108 can divide each of the GAA memory cell string 144 that is formed in the corresponding 0-shaped opening 103 into two sub-cells strings. Each of the memory cells 140 used to constitute the GAA memory cell string 144 can be divided into two memory cells 145 having an U-shaped channel profile; and the tunnel field-effect transistor switch 141 used to constitute the GAA memory cell string 144 can be divided into two tunnel field-effect transistor switches 141a and 141b with an U-shaped channel profile. The memory cells 145 and the tunnel field-effect transistor switch (such as the tunnel field-effect transistor switch 141a) that are stacked at the same side can be connected by the portion of the channel layer 124 disposed on the same sidewall 103b of the O-shaped opening 103 to form one of these two sub-cells strings; and these two sub-cells strings can be connected by the portion of the channel layer 124 disposed on the bottom 103a of the O-shaped opening 103 to form a U-shaped memory cell string 146. Such that, the U-shaped memory cell string 146 can have twice number of memory cells (i.e. the memory cells 140) as many as that the GAA memory cell string 144 has. In the present embodiment, the tunnel field-effect transistor switches 141a and 141b may serve as the inversion assist gates (IGs).

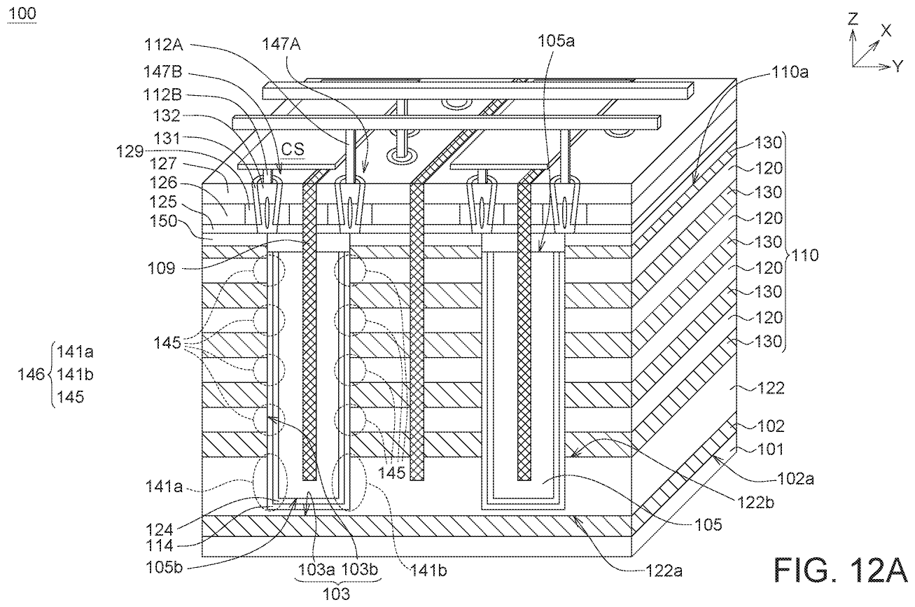

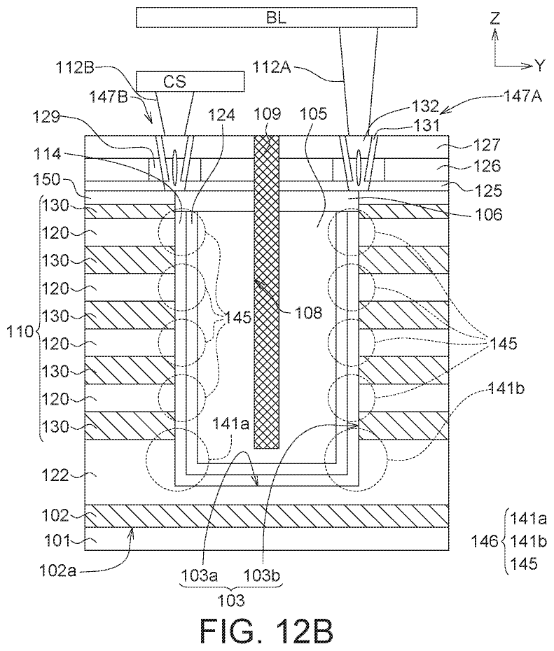

Subsequently, an isolation body 109 to fill the grooves 108; and after a series of downstream processes are carried out to form a plurality of interconnection structures for connecting the MOS transistor switch 147A and 147B to the corresponding bit lines or source lines, the 3D memory device 100 as shown in FIGS. 12A and 12B can be obtained. For example, in the present embodiment, each of the MOS transistor switches 147A connected to one end of the corresponding U-shaped memory cell string 146 is connected to a bit line BL by an interconnection structure 112A; and the corresponding MOS transistor switches 147B connected to the other end of the corresponding U-shaped memory cell string 146 is connected to a common source line CS by an interconnection structure 112B. Wherein, the MOS transistor switches 147A can serve as the string selection switch of the U-shaped memory cell string 146; and the MOS transistor switches 147B can serve as the ground selection switch of the U-shaped memory cell string 146.

Since the U-shaped memory cell string 146 of the 3D memory device 100 uses two MOS transistor switches 147A and 147B as the string/ground selection switches, thus it is possible to avoid the use of GIDL triggered by BBT to erase the U-shaped memory cell string 146. Therefore, the problems of failing turn on the string/ground selection switches during a subsequent programing operation due to charge accumulation can be solved.

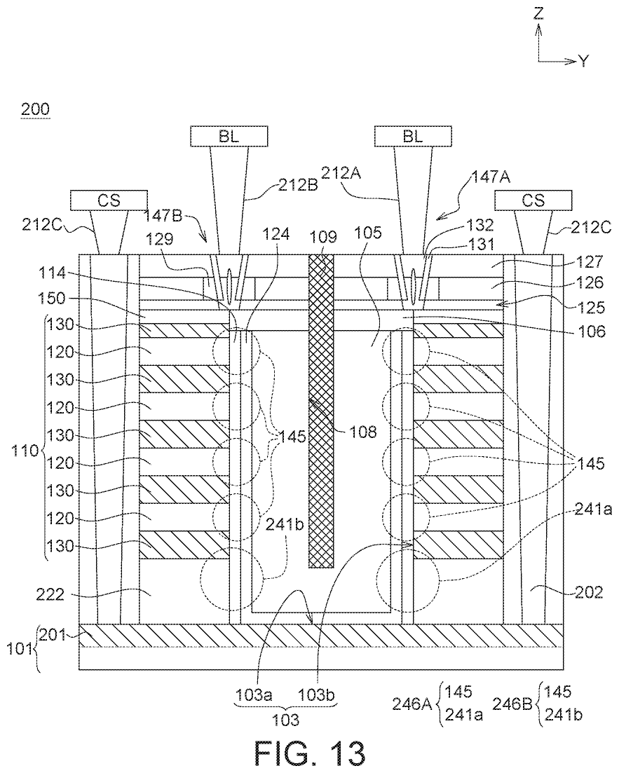

However, the 3D memory device using MOS transistor switches to serve as the string/ground selection switches is not limited to this regard. For example, FIG. 13 is a cross-sectional view illustrating a 3D memory device 200 in accordance with another embodiment of the present embodiment. The structure of the 3D memory device 200 is similar to that of the 3D memory device 100 as shown in FIGS. 12A and 12B, except that the 3D memory device 200 does not have the buried oxide layer 102 and further includes a source conductor layer 201 and a plurality of via plugs 202, wherein the source conductor layer 201 can be a doping region formed in the substrate 101, disposed underlying the multi-layers stacking structure 110 and in contact with the channel layer 124; and the via plugs 202 pass through the multi-layers stacking structure 110 and connecting the source conductor layer 201 with the common source line CS.

In the present embodiment, the memory cells 145 and the tunnel field-effect transistor switch 241a (or the tunnel field-effect transistor switch 246B) that are stacked at the same side can be connected by the portion of the channel layer 124 disposed on the same sidewall 103b of the O-shaped opening 103 to form an individual memory cell string 246A (or the memory cell string 246B), wherein the MOS transistor switches 147A and 147B can respectively serve as the string selection switches of the individual memory cell strings 246A and 246B, and can be respectively connected to two corresponding bit lines BL through the interconnection structures 212A and 212B.

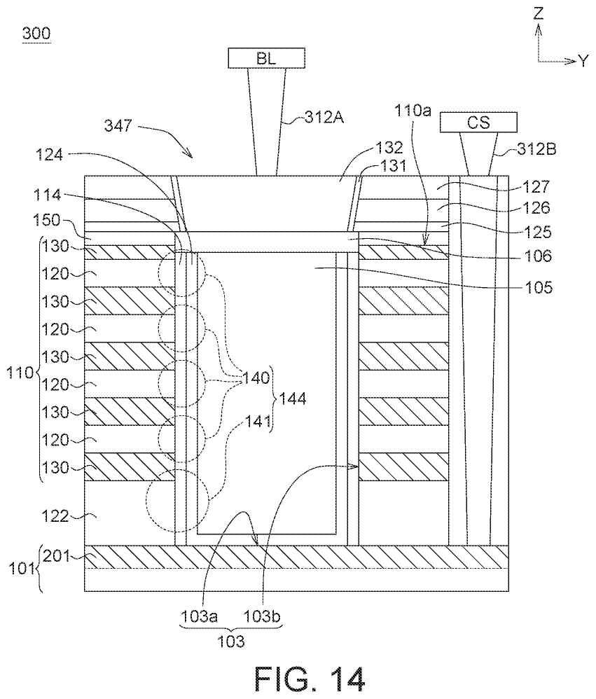

FIG. 14 is a cross-sectional view illustrating a 3D memory device 300 in accordance with yet another embodiment of the present embodiment. The structure of the 3D memory device 300 is similar to that of the 3D memory device 200 as shown in FIG. 13, except that the 3D memory device 300 does not include the grooves 108 to divide each of the memory cells 140 of the GAA memory cell strings 144 into two memory cells 145 and to divide the tunnel field-effect transistor switch 141 of the GAA memory cell string 144 into two tunnel field-effect transistor switches. Each GAA memory cell strings 144 of the 3D memory device 300 includes one single MOS transistor switch 347 to serve as the string selection switch and connecting to a corresponding bit line BL by an interconnection structure 312A; and each tunnel field-effect transistor switches 141 of the 3D memory device 300 can serve as the ground selection switch of the corresponding GAA memory cell string 144, and can be connected to a common source line CS through the source conductor layer 201, one of the via plugs 202 and an interconnection structure 312B.

In accordance with the aforementioned embodiments of the present disclosure, a 3 D memory device and the method for fabricating the same are provided. By using a switching element that does not have a gate dielectric layer including a multi-layers dielectric charge trapping structure to serve as a string selection switch/ground selection switch for a memory cell string in a 3D memory device, it is possible to avoid the use of GIDL triggered by BBT to erase the memory cell string. Therefore, the problems of failing turn on the string/ground selection switches during a subsequent programing operation due to charge accumulation can be solved.

In some embodiments of the present disclosure, the structure and method can be applied to a 3D memory device having GAA structure, a 3D memory device with a single-gate vertical channel (SGVC) structure, a 3D memory device with a cylindrical channel structure, a 3D memory device with an U-shaped vertical channel structure or a 3D memory device with a hemi-cylindrical channel structure.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A three-dimensional (3D) memory device, comprising:
a multi-layers stacking structure, comprising a plurality of conductive layers, a plurality of insulating layers, and at least one opening, wherein the plurality of insulating layer and the plurality of conductive layer are stacked along a stacking direction in a staggered manner, and the at least one opening passes through the plurality of conductive layers;
a memory layer, disposed in the at least one opening and at least partially overlapping the plurality of conductive layer a channel layer, disposed in the at least one opening and at least partially overlapping the memory layer; and
a switching element, comprising:
a channel plug, disposed over the multi-layers stacking structure and electrically connecting to the channel layer;
a gate dielectric layer, surrounding the channel plug; and
a gate, surrounding the gate dielectric layer.

2. The 3D memory device according to claim 1, wherein the channel layer has a U-shaped cross-sectional profile perpendicular to the stacking direction.

3. The 3D memory device according to claim 1, further comprising:
a landing contact pad, disposed in the at least one opening, respectively in contact with the channel plug and the channel layer, and insulated from the gate.

4. The 3D memory device according to claim 1, further comprising:
a source conductor layer, disposed underlying the multi-layers stacking structure and in contact with the channel layer and
a via plug, passing through the multi-layers stacking structure and in contact with the source conductor layer.

5. The 3D memory device according to claim 1, wherein the gate dielectric layer does not possess a dielectric charge trapping structure.

6. A method for fabricating a 3D memory device, comprising:
providing a multi-layers stacking structure comprising a plurality of conductive layers, a plurality of insulating layers, and at least one opening, wherein the plurality of insulating layer and the plurality of conductive layer are stacked along a stacking direction in a staggered manner, and the at least one opening passes through the plurality of conductive layers;
forming a memory layer in the at least one opening, at least partially and overlapping the plurality of conductive layer;
forming a channel layer in the at least one opening and at least partially overlapping the memory layer; and
forming a switching element over the multi-layers stacking structure, to make the switching element comprising:
a channel plug, electrically connecting to the channel layer;
a gate dielectric layer, without possessing a dielectric charge trapping structure and surrounding the channel plug; and
a gate, surrounding the gate dielectric layer.

7. The method according to claim 6, prior to forming the multi-layers stacking structure, further comprising:
filling the at least one opening to form a dielectric pillar;
forming a landing contact pad on the dielectric pillar, and in contact with the channel layer;
forming a dielectric protection layer overlying the landing contact pad and the multi-layers stacking structure;
forming a gate material layer overlying the dielectric protection layer;
forming a through hole passing through the gate material layer;
forming a gate dielectric layer formed on a sidewall of the through hole;
removing a portion of the dielectric protection layer to expose a portion of the landing contact pad through the through hole; and
filling the through hole with a channel material to form the channel plug.

8. The method according to claim 7, port to removing the portion of the dielectric protection layer, further comprising steps of forming a conductive film on the sidewall of the through hole to cover the gate dielectric layer.

9. The method according to claim 7, further comprising:
forming a groove, in one hand extending along a direction passing perpendicular to the stacking direction and beyond a sidewall of the at least one opening, so as to pass through the channel layer and the memory layer and to go into a portion of the multi-layers stacking structure; in another hand, extending downward along the stacking direction to pass through a portion of the gate material layer, a portion of the dielectric protection layer, the landing contact pad and a portion of the dielectric pillar aligning to the at least one opening; and

10. The method according to claim 9, further comprising forming a via plug passing through the multi-layers stacking structure and in contact with the channel layer.
